(19) United States
(12) Patent Application Publication
(10) Pub. No.: US 2022/0250077 A1
(43) Pub. Date: Aug. 11, 2022

(54) DIGITAL MICROFLUIDICS DEVICE WITH DROPLET PROCESSING COMPONENTS

(71) Applicant: HEWLETT-PACKARD DEVELOPMENT COMPANY, L.P., Spring, TX (US)

(72) Inventors: Michael W. Cumbie, Corvallis, OR (US); Viktor Shkolnikov, Palo Alto, CA (US); Chien-Hua Chen, Corvallis, OR (US)

(73) Assignee: HEWLETT-PACKARD DEVELOPMENT COMPANY, L.P., Spring, TX (US)

(21) Appl. No.: 17/611,287

(22) PCT Filed: Jul. 24, 2019
(86) PCT No.: PCT/US2019/043280

§ 371 Date: Nov. 15, 2021

(51) Int. Cl. B01L 3/00; B81B 7/02; B81C 99/00

(52) U.S. Cl. CPC B01L 3/502792; B01L 3/502715; B81B 7/02; B81C 99/0085; B01L 2300/0645; B01L 2300/0636; B81C 2201/034; B01L 2300/1827; B01L 2300/0816; B81B 2201/057; B81B 2203/0338; B81B 2203/04; B01L 2400/0424

(57) ABSTRACT

An example digital microfluidics device includes a device body having a primary substrate defining a planar primary substrate surface; a plurality of droplet processing components having respective component substrates overmolded in the primary substrate in a coplanar arrangement with the primary substrate surface; and an electrical interface carried on the primary substrate surface, the electrical interface defining a planar droplet manipulation surface and carrying a set of droplet manipulation electrodes adjacent to the droplet manipulation surface; the electrical interface configured to interconnect the droplet manipulation electrodes and at least a portion of the droplet processing components.

### BACKGROUND

Digital microfluidics systems may be used to perform a variety of chemical, biological, and biochemical processes by manipulating droplets of fluid. In some systems, the manipulation of droplets includes movement of the droplets through various portions of the system, as well as treatment of the droplets with heat, magnetic fields or the like.

### BRIEF DESCRIPTIONS OF THE DRAWINGS

FIG. 1 is a diagram of an example digital microfluidics device with overmolded droplet processing components.

FIG. 2 is a diagram of a further example digital microfluidics device with overmolded droplet processing components, including communication contacts and sets of differently-dimensioned droplet manipulation electrodes.

FIG. 3 is a side view of the example digital microfluidics device of FIG. 2.

FIG. 4 is a flowchart of an example method of manufacturing a digital microfluidics device with overmolded droplet processing components.

FIG. 5 is a flowchart of an example method of overmolding droplet processing components in the manufacture of a digital microfluidics device with overmolded droplet processing components.

FIG. 6 is a flowchart of an example method of applying an electrical interface in the manufacture of a digital microfluidics device with overmolded droplet processing components.

### DETAILED DESCRIPTION

Digital microfluidics (DMF) systems can be employed to implement a variety of analytical processes, some of which involve fluid manipulations. Beyond physical movement of droplets of fluid within the systems, some analytical processes also involve fluid manipulations such as the application of heat, the application of magnetic fields, and the like. Some analytical processes also involve sensing various properties of the fluid. Such fluid manipulations may be implemented by a plurality of distinct elements in a DMF system, such as distinct heating circuits, sensing circuits, and the like. Some DMF systems are fabricated as printed circuit boards (PCBs), with the above-mentioned circuits implemented as traces on a PCB. PCB fabrication may not, however, permit sufficiently precise structures for some fluid manipulations.

In addition, some analytical processes involve complex sequences of such fluid manipulations. Control circuitry capable of implementing such complex sequences may also be technically challenging, costly, or both, to fabricate on a substrate such as a PCB. Other substrates and fabrication techniques, such as monolithic silicon-based technologies, may be employed to fabricate a DMF system with sufficient precision to implement the above fluid manipulation circuits and control components. Such technologies require complex fabrication facilities and can lead to increased system cost.

To provide sufficiently precise fluid manipulation and control (e.g. sequencing) capabilities while reducing the cost and complexity of fabrication in comparison to, for example, the monolithic silicon-based system mentioned above, diverse fluid manipulation components are integrated into a DMF device as distinct, separately fabricated elements that are overmolded into a primary substrate such as an epoxy molding compound (EMC). Other fluid manipulation elements, which do not require the same degree of precision in their manufacture, can be fabricated on the overmolded assembly mentioned above, and interconnected with the overmolded components.

In the examples, the device comprises a device body having a primary substrate defining a planar primary substrate surface; a plurality of droplet processing components having respective component substrates overmolded in the primary substrate in a coplanar arrangement with the primary substrate surface; and an electrical interface carried on the primary substrate surface, the electrical interface defining a planar droplet manipulation surface and carrying a set of droplet manipulation electrodes adjacent to the droplet manipulation surface; the electrical interface configured to interconnect the droplet manipulation electrodes and at least a portion of the droplet processing components.

The plurality of droplet processing components can include at least one of: a sensor, a heater, a magnet, a droplet partitioning device, and a controller.

The droplet manipulation electrodes can include a first set of droplet manipulation electrodes having a first dimension, and a second set of droplet manipulation electrodes having a second dimension smaller than the first dimension.

The droplet partitioning device can be interconnected with the second set of droplet manipulation electrodes via the electrical interface.

The plurality of droplet processing components can include: a controller configured to implement an analytical process via the generation of control signals for one or more other droplet processing components; and a driver device configured to de-multiplex the control signals from the controller for transmission to the other droplet processing components.

The electrical interface can further comprise communication contacts for connecting the controller with an external device.

The primary substrate can include an epoxy molding compound (EMC), and the component substrates can include one or more semiconductor substrates distinct from the primary substrate.

At least one of the droplet manipulation electrodes disposed over at least one of the droplet processing components can include at least one of: a heating circuit, a sensing circuit, an electromagnetic circuit, or a dielectrophoretic circuit.

The electrical interface can include at least one redistribution layer carried on the primary substrate surface; and the at least one redistribution layer can define the droplet manipulation electrodes.

The device can further comprise a fluid conduit extending from the droplet manipulation surface to at least one of a droplet processing component and the primary substrate.

In some examples, the device comprises a plurality of droplet processing components; a primary substrate body overmolded on the droplet processing components to support the droplet processing components at a surface of the primary substrate body; a redistribution assembly over the surface of the primary substrate body, the redistribution assembly defining a droplet manipulation surface exposed to a droplet chamber; and an array of droplet manipulation electrodes connected with at least a subset of the droplet processing components via the redistribution assembly.

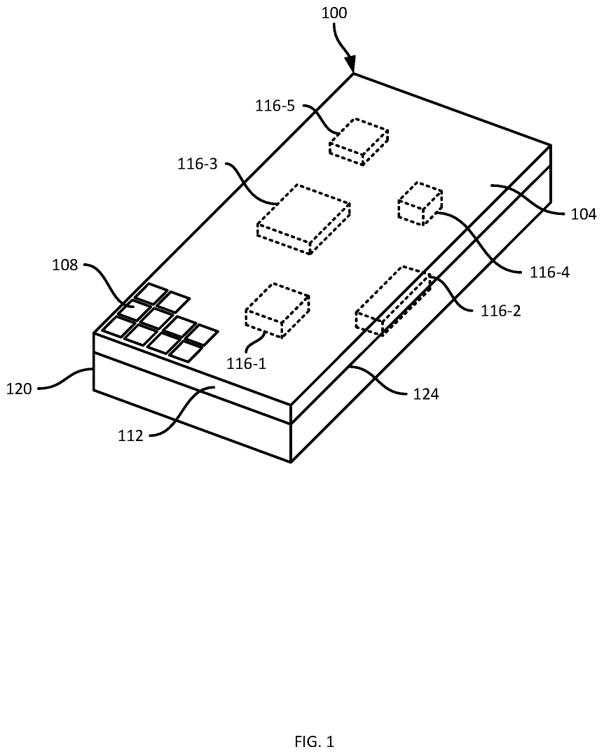

FIG. 1 shows an example digital microfluidics device 100 (also referred to herein simply as the device 100) with overmolded droplet processing components. The device 100 includes a planar droplet manipulation surface 104, which is the outermost surface shown in FIG. 1. A droplet manipulation chamber is defined above the droplet manipulation surface 104, for example, by a cover that is omitted from FIG. 1 to clearly illustrate underlying elements of the device 100. The droplet manipulation surface 104, in other words, is exposed to the chamber.

Movement of one or more droplets over the droplet manipulation surface 104 of the device 100 is performed by selectively energizing droplet manipulation electrodes 108, an array of which is disposed on or adjacent to the droplet manipulation surface 104. Only a subset of the droplet manipulation electrodes 108 are illustrated in FIG. 1, so as to illustrate other elements of the device 100. However, the full set of droplet manipulation electrodes 108 forms an array extending substantially over the entire area of the droplet manipulation surface 104.

The droplet manipulation electrodes 108 are carried on an electrical interface 112 that defines the droplet manipulation surface 104. The electrical interface 112 can include, for example, an outer insulating layer over the droplet manipulation electrodes 108 which forms the droplet manipulation surface, and on which droplets in the chamber lie. The electrical interface 112, in addition to conveying control signals to the droplet manipulation electrodes 108 to energize the droplet manipulation electrodes 108 as mentioned above, interconnects the droplet manipulation electrodes 108 and a plurality of droplet processing components.

As will be discussed in further detail below, the electrical interface 112 may also be referred to as a redistribution assembly. The electrical interface 112 can be implemented as one or more redistribution layers each supporting a plurality of conductive traces providing the above-mentioned interconnections. In some examples, the conductive traces of the outer-most redistribution layer of such a redistribution assembly (i.e. the layer closest to the droplet manipulation surface 104) define the droplet manipulation electrodes 108 themselves.

Example droplet processing components 116-1, 116-2, 116-3, 116-4 and 116-5 are shown in FIG. 1, and are referred to collectively as the droplet processing components 116, and generically as a droplet processing component 116.

As noted above, the droplet manipulation electrodes 108 can be selectively energized to move droplets about the droplet manipulation surface 104. The droplets can therefore be moved from an inlet location, mixed, moved to an outlet (e.g. waste) location, and the like. Some analytical processes performed by the device 100 may involve additional manipulations of the droplets. Examples of such additional manipulations include the application of heat, the application of magnetic fields, measurement of one or more droplet properties, partitioning of a droplet into multiple smaller droplets for further processing, and the like.

The droplet processing components 116 perform the additional fluid manipulations noted above. The droplet processing components 116 can therefore include a heater control unit, (e.g. an integrated circuit with one or more control inputs, as well as outputs to power a droplet manipulation electrode that includes a serpentine trace or other suitable circuit to heat a droplet), magnets (e.g. passive permanent magnets, electromagnets or the like), and sensors (e.g. an optical sensor, an ion sensor or the like). Some droplet processing components 116 can implement combinations of the above-mentioned elements. A further example of a droplet processing component 116 includes a droplet partitioning device, including a plurality of control outputs configured to selectively energize a specific array of droplet manipulation electrodes 108 to separate one or more droplets into a greater number of smaller droplets. The droplet manipulation electrodes 108 can therefore also take various forms, depending on the nature of the droplet processing components 116. For example, as mentioned above the droplet manipulation electrode 108 disposed over the above-mentioned heater control unit can include a serpentine heating trace. Other droplet manipulation electrodes can include sensing circuits, electromagnetic circuits, dielectrophoretic circuits, and the like. Each of the above-mentioned electrode structures can be controlled by an underlying droplet processing component 116.

The droplet processing components 116 can also include a controller, such as a field-programmable gate array (FPGA) that does not directly manipulate droplets, but controls other droplet processing components 116, droplet manipulation electrodes 108, or both. The droplet processing components 116 can further include a driver device that is configured to receive control signals from the controller and process the control signals for transmission to the appropriate droplet processing components (e.g. by de-multiplexing the control signals from the controller).

The droplet processing components 116 are heterogeneous, in that the droplet processing components 116 need not be fabricated using the same materials or fabrication processes. Further, the droplet processing components, rather than being fabricated with the remainder of the device 100, are fabricated separately and subsequently integrated into the device 100. The droplet processing components 116 therefore include respective component substrates, which are selected according to performance requirements, precision requirements and the like. For example, the controller mentioned above can be manufactured as a complementary metal-oxide semiconductor (CMOS) circuit from a monolithic silicon die. Other droplet processing components 116 can employ other component substrates, including semiconductor substrates (e.g. silicon-based substrates, PCB substrates), glass, ceramic substrates, and the like.

The droplet processing components 116 are integrated into the device 100 via overmolding in a primary substrate. Specifically, in the illustrated example the device 100 includes a device body 120 having a primary substrate. The primary substrate can be distinct from the component substrates of the droplet processing components 116. For example, the primary substrate can be an EMC or other suitable overmolding compound.

The device body 120 defines a planar primary substrate surface 124, on which the electrical interface 112 is carried. That is, the primary substrate surface 124 is shown at the boundary between the device body 120 and the electrical interface 112 in FIG. 1. The primary substrate is overmolded on the droplet processing components 116 to support the droplet processing components 116 at the primary substrate surface 124. In other words, respective surfaces of the droplet processing components 116 are in a coplanar arrangement with the primary substrate surface 124, while the remainder of each droplet processing component 116 is embedded within the device body 120.

The coplanar arrangement mentioned above exposes the coplanar surfaces of the droplet processing components 116 to the electrical interface 112 for interconnection with other droplet processing components 116 and/or with the droplet manipulation electrodes. The coplanar arrangement also places the droplet processing components 116 in close proximity to the droplet manipulation surface 104, enabling the droplet processing components 116 to act on droplets in the chamber to which the droplet manipulation surface 104 is exposed.

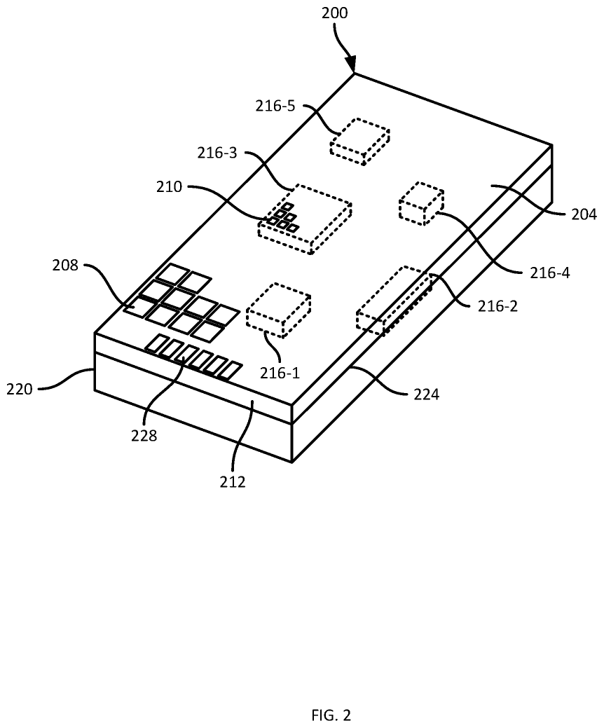

Turning to FIG. 2, another example of a DMF device 200 is illustrated. The device 100 includes a device body 220 having a primary substrate overmolded on a plurality of droplet processing components 216-1, 216-2, 216-3, 216-4 and 216-5. In the illustrated example, the droplet processing component 216-1 is a controller, the droplet processing component 216-2 is a driver device, the droplet processing component 216-3 is a droplet partitioning device, the droplet processing component 216-4 is a heater control unit combined with an optical sensor, and the droplet processing component 216-5 is a passive magnet.

The droplet processing components 216 are supported by the device body in a coplanar arrangement with a primary substrate surface 224 of the device body 220. The device 200 also includes an electrical interface 212 atop the primary substrate surface 224. The electrical interface 212 carries droplet manipulation electrodes 208. The droplet manipulation electrodes include a first set of droplet manipulation electrodes 208 with a first dimension (e.g. square electrodes with a first side length), and a second set of droplet manipulation electrodes 210 with a second dimension (e.g. square electrodes with a second side length). As seen in FIG. 2, the second dimension is smaller than the first dimension. The second set of droplet manipulation electrodes 210 can be disposed over a particular droplet processing component 216, such as the droplet partitioning device 216-3, which is configured to control the second set of droplet manipulation electrodes 210 (via the electrical interface 212) to partition a droplet into multiple smaller droplets.

The device 200 also includes, on the electrical interface 212 (e.g. on the droplet manipulation surface 204), a set of communication contacts 228 configured to connect the controller (e.g. the droplet processing component 216-1) to an external device, such as a computer. The controller 216-1 can be configured to receive instructions to initiate an analytical process, such as a quantitative polymerase chain reaction (QPCR) process, via the communication contacts 228. The controller 216-1 can then retrieve a sequence of operations corresponding to the relevant analytical process from an integrated memory of the controller 216-1, and can generate and transmit control signals to the other droplet processing components 216 and the droplet manipulation electrodes 208, e.g. via the driver device 216-2. The results of the analytical process can also be collected by the controller 216-1 and transmitted to the external device via the communication contacts 228.

The controller 216-1 may further be reprogrammed, for example by transmission of new instructions for storage in the above-mentioned memory, defining a sequence for a different analytical process.

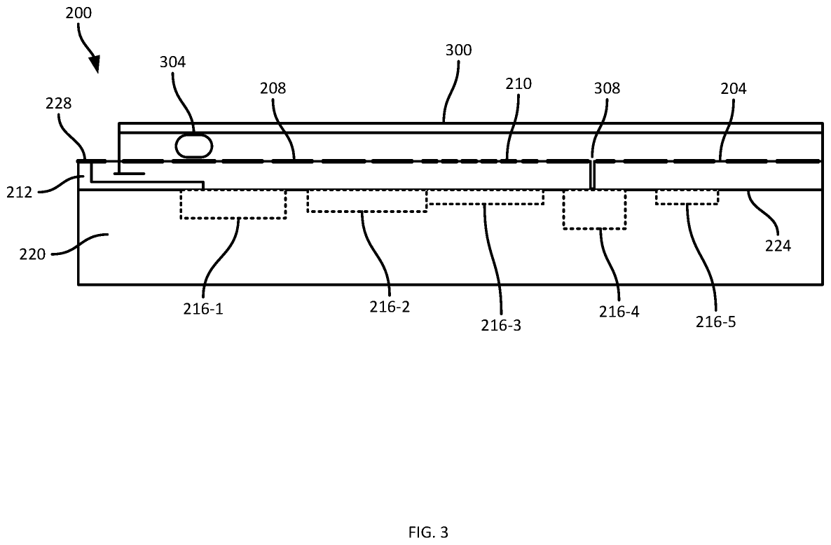

FIG. 3 shows a side view of the device 200, illustrating that the droplet processing components 216 are overmolded in the primary substrate of the device body 200 in a coplanar arrangement with the primary substrate surface 224. A lid or other suitable cover 300 of the device 200 is also shown, enclosing a chamber containing an example droplet 304. The cover 300 can include a conductive coating which may be connected to the electrical interface 212 for operation in concert with the droplet manipulation electrodes 208 and 210 to move droplets such as the droplet 304 over the droplet manipulation surface 204.

In addition, the device 200 as illustrated in FIG. 3 includes a fluid conduit 308 extending from the droplet manipulation surface 204 to a droplet processing component 216. The fluid conduit can extend from an opening in a droplet manipulation electrode 208 disposed over the droplet processing component 216 to the droplet processing component 216. Specifically, the fluid conduit 308 exposes a surface of the droplet processing component 216-3, for example to permit sensing of one or more properties of the fluid. Other example fluid conduits can extend through the primary substrate of the device body 220, for example to carry fluid to a waste receptacle.

In some examples, the device can be produced via a method comprising: selecting a plurality of droplet processing components; overmolding the selected droplet processing components with a primary substrate to form a device body having a planar primary substrate surface that is coplanar with the droplet processing components; applying an electrical interface on the primary substrate surface to define a planar droplet manipulation surface; and applying a set of droplet manipulation electrodes adjacent to the droplet manipulation surface.

The overmolding of selected droplet processing components can include: mounting the selected droplet processing components to a carrier; applying the primary substrate over the selected droplet processing components; and removing the carrier.

Applying the electrical interface can include: applying at least one planar semiconducting layer to the primary substrate surface; and applying conductive traces on the planar semiconducting layer, connected to at least a subset of the droplet processing components.

Applying the set of droplet manipulation electrodes can include applying further conductive traces on the planar semiconducting layer to form the droplet manipulation electrodes.

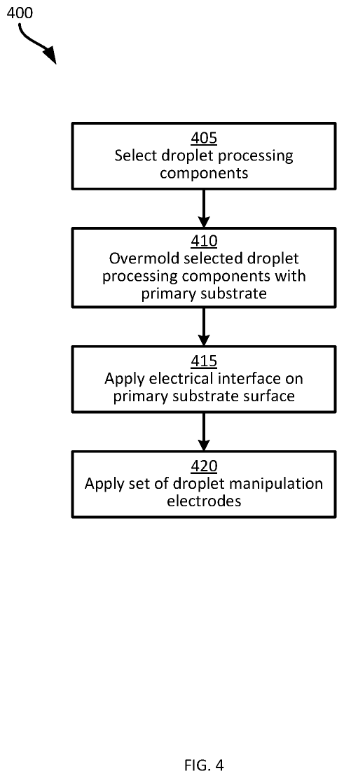

Referring to FIG. 4, a flowchart of a method 400 for manufacturing a DMF device with overmolded droplet processing components is illustrated. At block 405, droplet processing components (e.g. the droplet processing components 116 and/or 216 mentioned above) are selected, e.g. via a pick-and-place mechanism. Which droplet processing components are selected can be based on the intended application of the resulting DMF device. For example, if the DMF device is to be employed for a particular analytical process, or a set of analytical processes, the droplet processing components selected at block 405 may be components that enable the various fluid manipulations involved in the above process(es).

At block 410, the selected droplet processing components 116 or 216 are overmolded with a primary substrate, such as an EMC, to form the device body 100 or 200. At block 415, the electrical interface 112 or 212 is applied on the primary substrate surface 124 or 224 of the device body 100 or 200.

At block 420, a set of droplet manipulation electrodes 108, 208 and/or 210 are applied to the electrical interface, at or adjacent to the droplet manipulation surface 104 or 204 formed by the electrical interface.

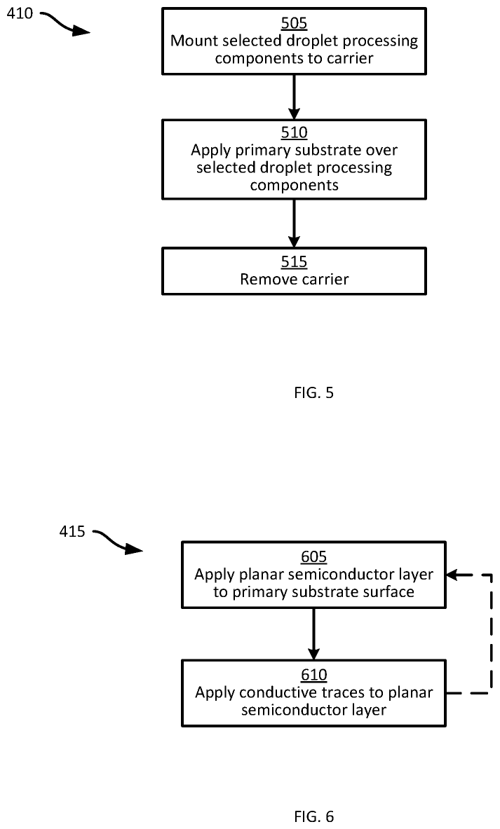

Various techniques can be employed to perform the above-mentioned steps of the method 400. Turning to FIG. 5, an example method of performing block 410 of the method 400 is illustrated. In the example of FIG. 5, overmolding of the droplet processing components 116 or 216 is performed by, at block 505, mounting the selected droplet processing components 116 or 216 on a planar carrier, e.g. via tape or another suitable fastener.

At block 510, the primary substrate is applied over the mounted droplet processing components 116 or 216 to form the device body 100 or 200. At block 515, the carrier is removed (as well as the tape or other fastener, as applicable), exposing the primary substrate surface 124 or 224 and the coplanar surfaces of the droplet processing components 116 or 216.

Referring to FIG. 6, an example method of performing block 415 of the method 400 is illustrated. In the example of FIG. 6, application of the electrical interface 112 or 212 is performed by, at block 605, applying a planar semiconductor layer (e.g. SU8 or other suitable photoresist compound) to the primary substrate surface 124 or 224. At block 610, conductive traces are applied to the planar semiconductor layer to define interconnections between the droplet processing components 116 or 216. The performance of blocks 605 and 610 can be repeated, for example to apply a second semiconductor layer and further traces defining the droplet manipulation electrodes 108, 208 and/or 210.

The use of discrete components overmolded into the primary substrate along with further components fabricated on the primary substrate enables the provision of complex and/or costly components in certain portions of the DMF device, while employing lower-cost and/or lower-complexity components in the remaining portions of the DMF device. The overall cost and complexity of the DMF device may therefore be reduced in comparison to monolithic silicon-based devices, while retaining sufficient levels of precision in the fluid manipulation capabilities of the DMF device.

It should be recognized that features and aspects of the various examples provided above can be combined into further examples that also fall within the scope of the present disclosure. In addition, the figures are not to scale and may have size and shape exaggerated for illustrative purposes.

1. A digital microfluidics device comprising:
a device body having a primary substrate defining a planar primary substrate surface;
a plurality of droplet processing components having respective component substrates overmolded in the primary substrate in a coplanar arrangement with the primary substrate surface; and
an electrical interface carried on the primary substrate surface, the electrical interface defining a planar droplet manipulation surface and carrying a set of droplet manipulation electrodes adjacent to the droplet manipulation surface; the electrical interface configured to interconnect the droplet manipulation electrodes and at least a portion of the droplet processing components.

2. The digital microfluidics device of claim 1, wherein the plurality of droplet processing components include at least one of: a sensor, a heater, a magnet, a droplet partitioning device, and a controller.

3. The digital microfluidics device of claim 2, wherein the droplet manipulation electrodes include a first set of droplet manipulation electrodes having a first dimension, and a second set of droplet manipulation electrodes having a second dimension smaller than the first dimension.

4. The digital microfluidics device of claim 3, wherein the droplet partitioning device is interconnected with the second set of droplet manipulation electrodes via the electrical interface.

5. The digital microfluidics device of claim 1, wherein the plurality of droplet processing components include:
a controller configured to implement an analytical process via the generation of control signals for one or more other droplet processing components; and
a driver device configured to de-multiplex the control signals from the controller for transmission to the other droplet processing components.

6. The digital microfluidics device of claim 5, wherein the electrical interface further comprises communication contacts for connecting the controller with an external device.

7. The digital microfluidics device of claim 1, wherein the primary substrate includes an epoxy molding compound (EMC), and wherein the component substrates include one or more semiconductor substrates distinct from the primary substrate.

8. The digital microfluidics device of claim 1, wherein at least one of the droplet manipulation electrodes disposed over at least one of the droplet processing components includes at least one of: a heating circuit, a sensing circuit, an electromagnetic circuit, or a dielectrophoretic circuit.

9. The digital microfluidics device of claim 1, wherein the electrical interface includes at least one redistribution layer carried on the primary substrate surface; and wherein the at least one redistribution layer defines the droplet manipulation electrodes.

10. The digital microfluidics device of claim 1, further comprising a fluid conduit extending from the droplet manipulation surface to at least one of a droplet processing component and the primary substrate.

11. A method comprising:
selecting a plurality of droplet processing components;
overmolding the selected droplet processing components with a primary substrate to form a device body having a planar primary substrate surface that is coplanar with the droplet processing components;
applying an electrical interface on the primary substrate surface to define a planar droplet manipulation surface; and
applying a set of droplet manipulation electrodes adjacent to the droplet manipulation surface.

12. The method of claim 11, wherein overmolding the selected droplet processing components includes:
mounting the selected droplet processing components to a carrier;
applying the primary substrate over the selected droplet processing components; and
removing the carrier.

13. The method of claim 11, wherein applying the electrical interface includes:
applying at least one planar semiconducting layer to the primary substrate surface; and
applying conductive traces on the planar semiconducting layer, connected to at least a subset of the droplet processing components.

14. The method of claim 13, wherein applying the set of droplet manipulation electrodes includes applying further conductive traces on the planar semiconducting layer to form the droplet manipulation electrodes.

15. A digital microfluidics device comprising:
a plurality of droplet processing components;
a primary substrate body overmolded on the droplet processing components to support the droplet processing components at a surface of the primary substrate body;
a redistribution assembly over the surface of the primary substrate body, the redistribution assembly defining a droplet manipulation surface exposed to a droplet chamber; and
an array of droplet manipulation electrodes connected with at least a subset of the droplet processing components via the redistribution assembly.
